(19) United States
(12) Patent Application Publication
(10) Pub. No.: US 2020/0161128 A1
(43) Pub. Date: May 21, 2020

(54) SEMICONDUCTOR DEVICE AND MANUFACTURING METHOD THEREOF

(71) Applicant: NANYA TECHNOLOGY CORPORATION, New Taipei City (TW)

(72) Inventor: Szu-Han CHEN, New Taipei City (TW)

(21) Appl. No.: 16/196,671

(22) Filed: Nov. 20, 2018

(51) Int. Cl. H01L 21/02; H01L 21/768

(52) U.S. Cl. CPC H01L 21/02337; H01L 21/02271; H01L 21/76892

(57) ABSTRACT

The present disclosure provides a semiconductor device and a manufacturing method thereof. The semiconductor device includes a patterned insulation layer, a stud and a landing pad. The patterned insulation layer has an opening. The stud is disposed in the opening. The landing pad is disposed on the patterned insulation layer. The stud and the landing pad are integrally formed.

### TECHNICAL FIELD

The present disclosure relates to a semiconductor device and a manufacturing method thereof, and more particularly, to a method of manufacturing a semiconductor device by a deposition process.

### DISCUSSION OF THE BACKGROUND

In order to make more efficient use of integrated circuit surface area, conventional two-dimensional semiconductor technology has evolved such that contemporary circuits are formed on multiple layers in a three-dimensional configuration. In such configurations, active devices and interconnects are formed in a layered arrangement. During the formation of each subsequent layer, an inter-layer pathway, referred to in the art as a “plug” or a “stud,” is electrically coupled between the various active devices and transmission lines of the different layers. To assist in aligning a plug, “landing pads” or “taps” are formed in lower layers to serve as a target for the plugs extending from the upper layer. The landing pads are coupled to an underlying circuit or interconnect and are generally larger in surface area than the circuit or interconnect to serve as a wider-tolerance target for the plug.

Such multi-layered technology has enabled the design of highly-integrated memory devices, for example DRAM devices, having extremely high capacity, for example above 1 gigabyte. Such DRAM devices include multiple arrays of memory cells, densely and efficiently laid out under tight design constraints. Between the cell areas are peripheral regions, which include supporting circuitry and interconnect circuitry between the cells, as well as input peripherals and the like.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a semiconductor device. The semiconductor device includes a patterned insulation layer, a stud and a landing pad. The patterned insulation layer has an opening. The stud is disposed in the opening. The landing pad is disposed on the patterned insulation layer. The stud and the landing pad are integrally formed.

In some embodiments, the landing pad exposes one-half of the stud.

In some embodiments, the landing pad exposes one-third of the stud.

In some embodiments, the landing pad is disposed on the stud.

In some embodiments, the landing pad is disposed on one-half of the stud.

In some embodiments, the landing pad is disposed on two-thirds of the stud.

Another aspect of the present disclosure provides a method of manufacturing a semiconductor device. The method includes receiving a substrate. The method further includes forming a patterned dielectric layer having an opening on the substrate. The method further includes forming a conductive layer on the patterned dielectric layer and in the opening. The method further includes forming a landing pad on the patterned dielectric layer by patterning the conductive layer.

In some embodiments, the formation of the conductive layer on the patterned dielectric layer and in the opening includes: forming the conductive layer on the patterned dielectric layer and in the opening by a chemical vapor deposition (CVD).

In some embodiments, the formation of the conductive layer on the patterned dielectric layer and in the opening includes: forming the conductive layer on the patterned dielectric layer and in the opening by plasma-enhanced CVD (PECVD).

In some embodiments, the formation of the landing pad on the patterned dielectric layer by patterning the conductive layer includes: exposing a portion of a portion of the conductive layer, wherein the portion of the conductive layer is formed in the opening.

In some embodiments, the formation of the landing pad on the patterned dielectric layer by patterning the conductive layer further includes: exposing the entire patterned dielectric layer except for a portion of the patterned dielectric layer under the landing pad.

In some embodiments, the exposure of the portion of the portion of the conductive layer includes: exposing one-third of the portion of the conductive layer.

In some embodiments, the exposure of the portion of the portion of the conductive layer includes: exposing one-half of the portion of the conductive layer.

Another aspect of the present disclosure provides a method of designing and manufacturing a device. The method includes measuring a resistance of a combination of a landing pad and a stud of a manufactured semiconductor device, wherein both the landing pad and the stud are in a patterned conductive layer of the manufactured semiconductor device. The method further includes adjusting a thickness of a patterned conductive layer in a semiconductor device to be manufactured, wherein the adjusting is performed when the resistance is not optimal. The method further includes manufacturing the semiconductor device according to the thickness.

In some embodiments, the adjustment of the thickness of the patterned conductive layer in the semiconductor device to be manufactured includes: adjusting a thickness of a portion of the patterned conductive layer, wherein the portion of the patterned conductive layer is disposed on a patterned dielectric layer of the semiconductor device to be manufactured.

In the present disclosure, since a process of forming the landing pad does not undergo the CMP process and the PVD process following the CMP process, the method of manufacturing the semiconductor device is relatively simple. In addition, since the landing pad and the stud are integrally formed and have the same material, there is no need to provide an adhesive layer therebetween. Also, there is no need for concern whether an adhesion between the landing pad and the stud is sufficient. Moreover, since no CMP process is performed, there is no need for concern whether a mark for alignment in the subsequent photolithography process is damaged.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should be understood to be connected to the figures' reference numbers, which refer to similar elements throughout the description.

FIGS. 1 to 6 are cross-sectional diagrams showing intermediate steps of a comparative method of manufacturing a semiconductor device.

FIG. 7 is a top view illustrating problems caused by a chemical mechanical planarization (CMP) process adopted in the comparative process.

FIG. 8 is a schematic diagram of a landing pad of a semiconductor device positioned in an offset position.

FIG. 9 is a schematic diagram of a landing pad of a semiconductor device positioned in another offset position.

FIGS. 10 to 12 are cross-sectional diagrams showing intermediate steps of a method of manufacturing a semiconductor device, in accordance with some embodiments of the present disclosure.

FIG. 13 is a flowchart of a method of manufacturing a semiconductor device, in accordance with some embodiments of the present disclosure.

FIG. 14 is a flowchart of a method of designing and manufacturing a device, in accordance with some embodiments of the present disclosure.

FIG. 15 is a schematic diagram illustrating a design flow of an integrated circuit (IC), in accordance with some embodiments.

### DETAILED DESCRIPTION

Embodiments of the disclosure are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Throughout the various views and illustrative embodiments, like reference numerals are used to designate like elements. Reference will now be made in detail to exemplary embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, an apparatus in accordance with the present disclosure. It should be understood that elements not specifically shown or described may take various forms. Reference throughout this specification to “some embodiments” or “an embodiment” means that a particular feature, structure, or characteristic described in connection with the embodiment is included in at least one embodiment. Thus, the appearances of the phrases “in some embodiments” or “in an embodiment” in various places throughout this specification do not necessarily refer to the same embodiment. Furthermore, the particular features, structures, or characteristics may be combined in any suitable manner in one or more embodiments.

In the drawings, like reference numbers are used to designate like or similar elements throughout the various views, and illustrative embodiments of the present invention are shown and described. The figures are not necessarily drawn to scale, and in some instances the drawings have been exaggerated and/or simplified in places for illustrative purposes only. A person having ordinary skill in the art will appreciate the many possible applications and variations of the present invention based on the following illustrative embodiments of the present invention.

Unless otherwise defined, all terms (including technical and scientific terms) used herein have the same meaning as that commonly understood by a person having ordinary skill in the art to which the embodiments of the present disclosure belong. It should be understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

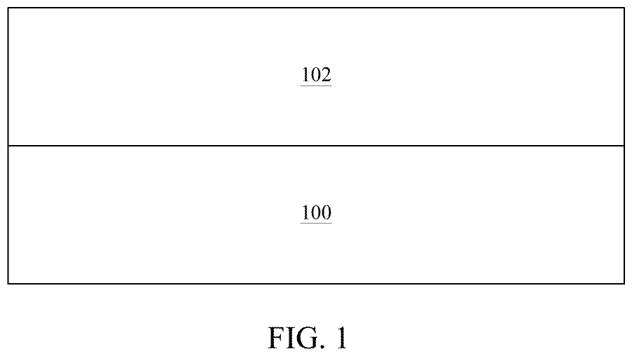

FIGS. 1 to 6 are cross-sectional diagrams showing intermediate steps of a comparative method of manufacturing a semiconductor device. Referring to FIG. 1, a substrate 100 is received.

In some implementations, the substrate 100 includes a wafer over which devices such as semiconductor devices or other devices are formed. In some implementations, the substrate 100 includes a semiconductor substrate, such as a bulk semiconductor substrate. The bulk semiconductor substrate includes an elementary semiconductor, such as silicon or germanium; a compound semiconductor, such as silicon germanium, silicon carbide, gallium arsenic, gallium phosphide, indium phosphide, or indium arsenide; or combinations thereof. In some implementations, the substrate 100 includes a multilayered substrate, such as a silicon-on-insulator (SOI) substrate, which includes a bottom semiconductor layer, a buried oxide layer (BOX) and a top semiconductor layer.

In some implementations, the substrate 100 may be a p-type doped substrate or an n-type doped substrate, which means that the semiconductor substrate 100 may be doped with either n-type or p-type impurities. A p-type material may be further classified as a p++, p+, p, p−, or p−−type material, depending on the concentration of the dopant. If a material is stated to be a p-type material, it is doped with p-type impurities and it may be any of the p++, p+, p, p−, or p−−type materials. Similarly, an n-type material may be further classified as an n++, n+, n, n−, or n−−type material. If a material is stated to be an n-type material, it is doped with n-type impurities and it may be any of the n++, n+, n, n−, or n−−type materials. Dopant atoms for p-type materials include boron, for example. In n-type materials, dopant atoms include phosphorous, arsenic, and antimony, for example. Doping may be performed through ion implantation processes. In some implementations, the substrate 100 is formed from silicon, gallium arsenide, silicon germanium, silicon carbon, or other known semiconductor materials used in semiconductor device processing.

Next, a dielectric layer 102 is formed on the substrate 100 by any acceptable deposition process, such as spin coating, chemical vapor deposition (CVD), laminating, the like, or a combination thereof.

In some implementations, the dielectric layer 102 is a single-layered structure, which may be formed of a dielectric material such as silicon oxide, silicon nitride or other suitable dielectric or insulative material. In some implementations, the dielectric layer 102 is a multi-layered structure, which includes a plurality of dielectric films. For example, the multi-layered dielectric layer includes a silicon oxide-silicon nitride (ON) dielectric layer, a silicon oxide-silicon nitride-silicon oxide (ONO) dielectric layer, or any other suitable dielectric film stack.

In some implementations, the dielectric layer 102 may be formed of a polymer, which may also be a photo-sensitive material such as polybenzoxazole (PBO), polyimide, benzocyclobutene (BCB), or the like. In accordance with alternative implementations of the present disclosure, the dielectric layer 102 is formed of inorganic material(s), which may be a nitride such as silicon nitride, an oxide such as silicon oxide, PhosphoSilicate Glass (PSG), BoroSilicate Glass (BSG), boron-doped PhosphoSilicate Glass (BPSG), or the like.

In some implementations, the dielectric layer 102 may include silicon oxide, silicon nitride, silicon oxynitride, a high-k dielectric material, combinations thereof, or multi-layers thereof. The high-k dielectric material may comprise TiO₂, HfZrO, Ta₂O₃, HfSiO₄, ZrO₂, ZrSiO₂, combinations thereof, or other suitable material. The dielectric layer 102 may have a thickness between about 100 Å and about 2,500 Å, although different thicknesses may be used.

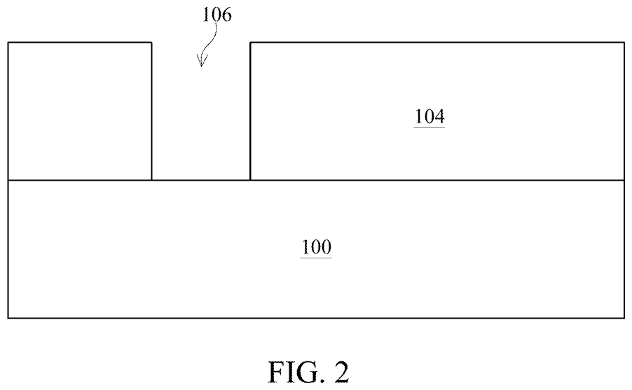

Referring to FIG. 2, a patterned dielectric layer 104 having an opening 106 is formed on the substrate 100 by patterning the dielectric layer 102 shown in FIG. 1. For example, a resist layer such as a photoresist layer is formed on the dielectric layer 102, and the resist layer is patterned by photolithography or any other suitable patterning technique. Next, the patterned dielectric layer 104 is formed by using the patterned resist layer to pattern the dielectric layer 102.

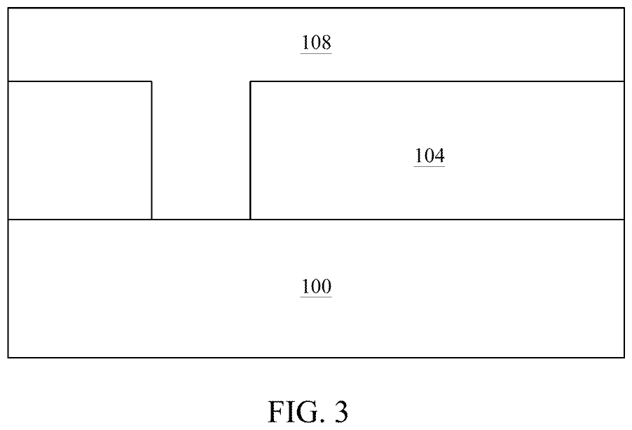

Referring to FIG. 3, a conductive layer 108 is formed on the patterned dielectric layer 104 and in the opening 106 by, for example, depositing a conductive material into the opening 106 and on a surface of the patterned conductive layer 104. In some implementations, the operation shown in FIG. 3 is performed not only to form a stud in the opening 106 but also to form a contact (not shown) in another opening (not shown) in the patterned conductive layer 104. In some implementations, because of a relatively high aspect ratio of the opening 106 and the opening in which the contact is to be formed, a chemical vapor deposition (CVD) is performed, and in an alternative implementation, a plasma-enhanced CVD (PECVD) is adopted.

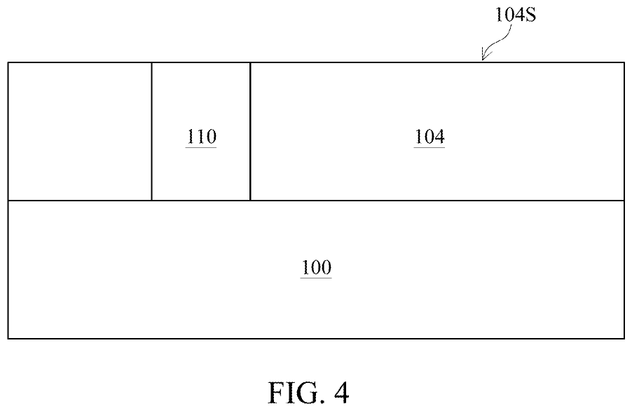

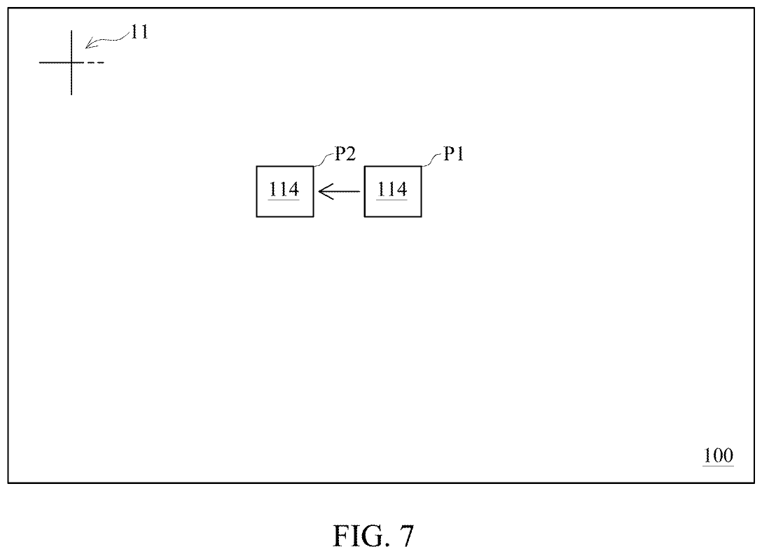

Referring to FIG. 4, a stud 110 is formed in the opening 106 of the patterned conductive layer 104 by, for example, a chemical mechanical planarization (CMP) process. The stop timing of the CMP process cannot be well controlled. As a result, a surface portion 104S, on which a mark 11 shown in FIG. 7 for alignment in the subsequent photolithography process is formed, of the patterned dielectric layer 104, will be inevitably removed or slightly damaged.

In some implementations, assuming an underlying tungsten plug, the stud 110 may be formed by first providing a Ti layer, for example by the CVD, to a thickness of 100 Angstroms. This is followed by providing a layer of TiN, for example by the CVD or atomic layer deposition (ALD), to a thickness of 300 Angstroms, followed by providing a layer of tungsten (W) of approximately 2000 Angstroms in thickness. The resulting structure is polished by chemical-mechanical polishing.

In some implementations, assuming an underlying TiN plug, the stud 110 may be formed by first providing a Ti layer, for example by a CVD, to a thickness of 100 Angstroms. This is followed by providing a layer of TiN, for example by the CVD or an ALD, to a thickness of 1500 Angstroms, followed by a chemical-mechanical polishing process.

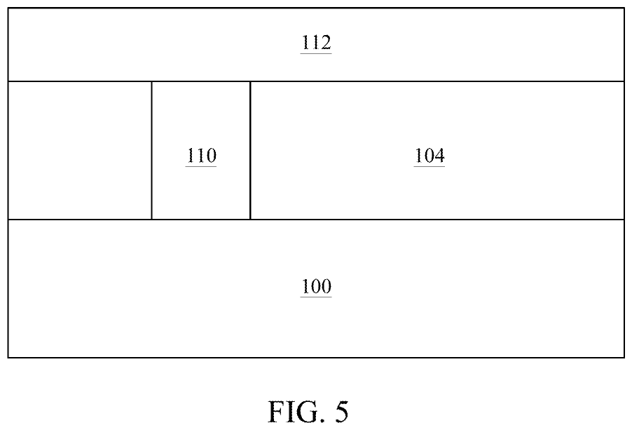

Referring to FIG. 5, a conductive layer 112 is formed on the patterned dielectric layer 104 and the stud 110 by, for example, a physical vapor deposition (PVD). In some implementations, a material of the conductive layer 112 is different from a material of the patterned conductive layer 104. To form the conductive layer 112 on the patterned conductive layer 104, an adhesive layer (not shown) is required to adhere the conductive layer 112 to the patterned conductive layer 104.

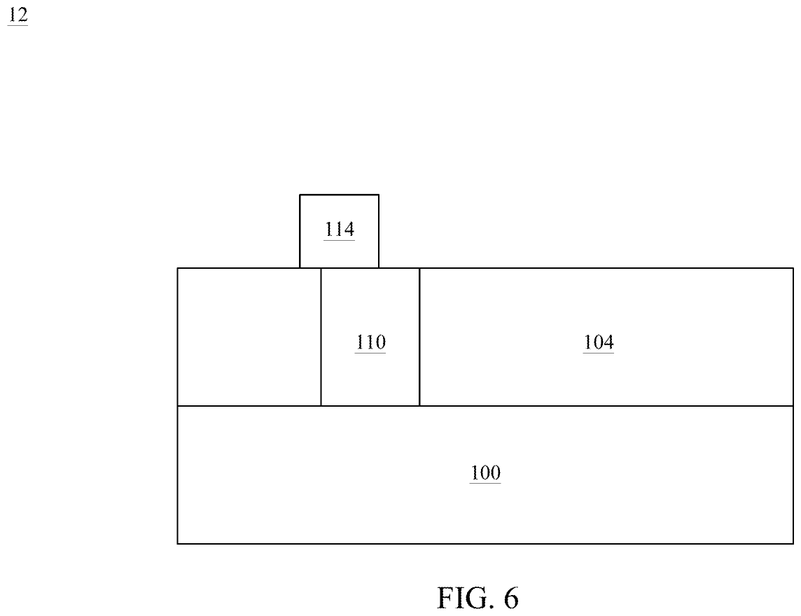

Referring to FIG. 6, a semiconductor device 12 is formed. A landing pad 114 is formed on the stud 110 and the patterned conductive layer 104 by patterning the conductive layer 112 shown in FIG. 5.

In summary, as shown in FIGS. 1 to 6, to form the landing pad 114, the comparative method is relatively complicated because of three-step process of the CVD process, the CMP process and the PVD process. Moreover, as mentioned above, it is necessary to consider adhesive force between two different conductive materials. If the adhesive force is not sufficient to adhere the landing pad 114 to the stud 110 because of, for example, the relatively thick and heavy landing pad 114, the landing pad 114 may collapse. As a result, an electrical signal which would otherwise be transmitted through the landing pad 114 cannot be completely transmitted.

FIG. 7 is a top view illustrating problems caused by a chemical mechanical planarization (CMP) process adopted in the comparative method. Referring to FIG. 7 and FIG. 4, the mark 11 formed on the surface portion 104S of the patterned dielectric layer 104 is damaged, as depicted by a dotted line, by the CMP process, resulting in shift from an ideal position P1 of the landing pad 114 to an offset position P2 of the landing pad 114.

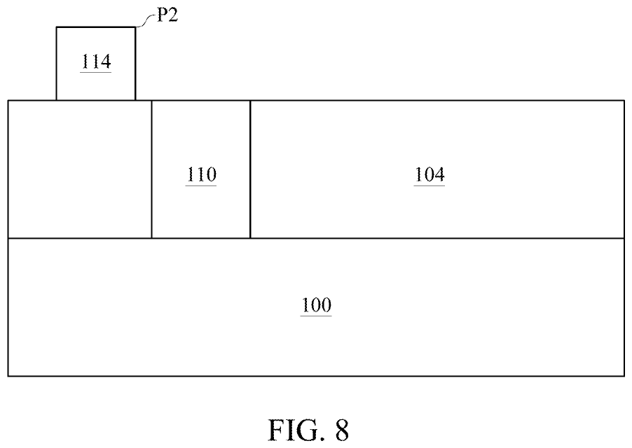

FIG. 8 is a schematic diagram of the landing pad 114 of a semiconductor device positioned in the offset position P2. Referring to FIG. 8 and FIG. 7, because of the damaged mark 11, the landing pad 114 does not overlap the stud 110, forming an open circuit. The landing pad 114 cannot receive an electrical signal transmitted from the stud 110.

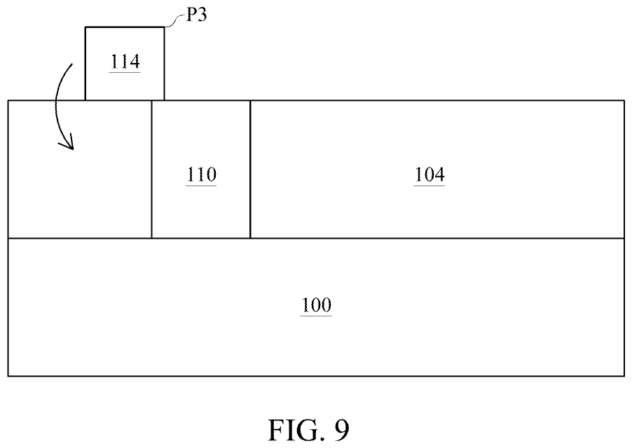

FIG. 9 is a schematic diagram of the landing pad 114 of a semiconductor device positioned in another offset position P3. Referring to FIG. 9, similar to the discussion provided in the embodiment of FIG. 8, because of the damaged mark 11, although the landing pad 114 overlaps the stud 110, an overlap area is not sufficient to let the stud 110 support the landing pad 114. As a result, the landing pad 114 will collapse if the patterned conductive layer 104 is removed by, for example, an etching process.

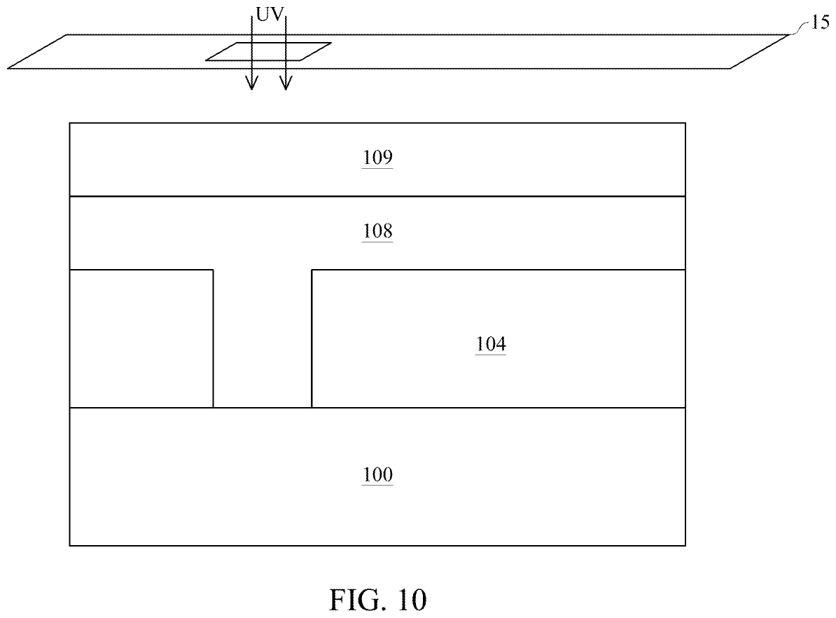

FIGS. 10 to 12 are cross-sectional diagrams showing intermediate steps of a method of manufacturing a semiconductor device, in accordance with some embodiments of the present disclosure. It should be understood that FIG. 10 to FIG. 12 have been simplified to better facilitate a clear understanding of various embodiments of the present disclosure.

Referring to FIG. 10, following the intermediate step shown in

FIG. 3, a photoresist layer 109 is formed on the conductive layer 108 by, for example, a priming process, a coating process and a soft bake process, which are performed in order. In the present embodiment, the photoresist layer 109 includes a positive photoresist. However, the disclosure is not limited thereto. In other embodiments, the photoresist layer 109 includes a negative photoresist.

Next, a photomask 15 having a pattern is provided. Light, such as ultraviolet (UV) light, irradiates the photoresist layer 109 via the photomask 15. Accordingly, the pattern of the photomask 15 is transferred onto the photoresist layer 109. For a positive photoresist, a portion of the positive layer exposed to the light remains, and other portions are removed.

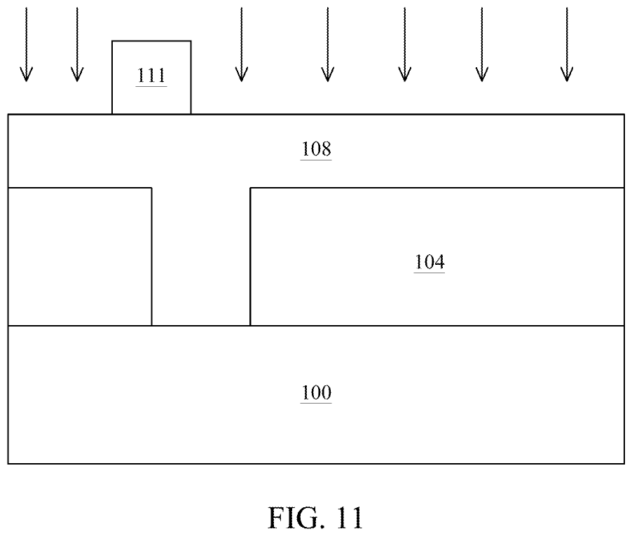

Referring to FIG. 11, a patterned photoresist layer 111 is formed on the conductive layer 108 by, for example, a development process on the photoresist layer 109, followed by a hard bake process.

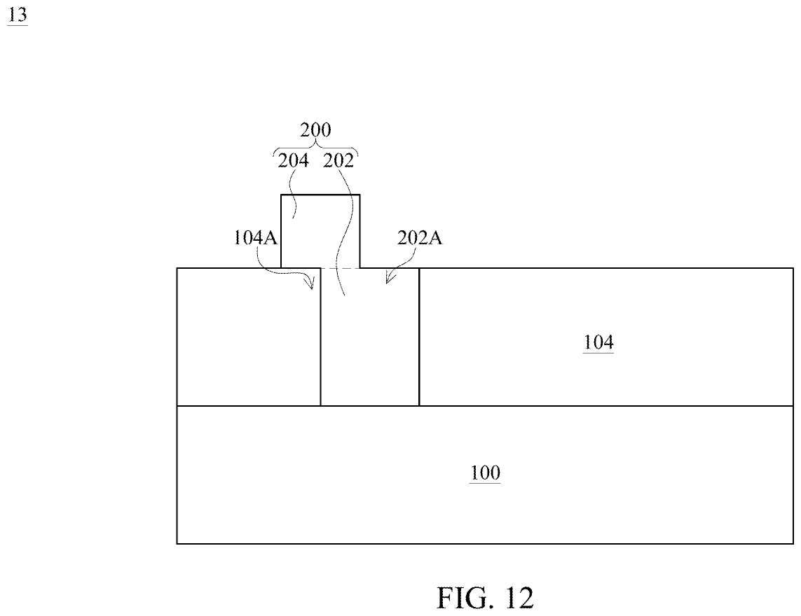

Referring to FIG. 12, a patterned conductive layer 200 is formed by patterning the conductive layer 108, using the patterned photoresist layer 111 as a mask during the etching process.

During the etching process, for example, an etching gas is used. In an embodiment, the etch chemistry includes fluorine-containing gas (e.g., CF₄, C₄F₈, C₅F₈, C₆F₈, SF₆, CH₂F₂, CHF₃, and/or C₂F₆), chlorine-containing gas (e.g., Cl₂, CHCl₃, CCl₄, and/or BCl₃), bromine-containing gas (e.g., HBr and/or CHBr₃), oxygyn-containing gas, iodine-containing gas, other suitable gases and/or plasmas, or combinations thereof. In another embodiment, the etch chemistry includes Cl₂, BCl₃, Ar, fluorine-based chemistry, HF-based chemistry, NH₄OH, the combination of NH₄OH and H₂O₂, the combination of HCl and H₂O₂, the combination of H₂SO₄ and H₂O₂, or other suitable materials. The etching process may include a multiple-step etching to improve etch selectivity, flexibility and desired etch profile. The patterned photoresist layer 111 is removed after the formation of the patterned conductive layer 200.

A portion 204 of the patterned conductive layer 200, serving as a landing pad, is accordingly formed on the patterned dielectric layer 104. The other portion 202 of the patterned conductive layer 200, serving as a stud, is also accordingly formed in the opening 106 of the patterned dielectric layer 104. A portion 202A of the portion 202 of the patterned conductive layer 200 is exposed by the landing pad 204. The patterned dielectric layer 104 is entirely exposed by the landing pad 204 except for a portion 104A of the patterned dielectric layer 104 under the landing pad 204. Both the stud 202 and the landing pad 204 derive from the conductive layer 108. The stud 202 and the landing pad 204 are integrally formed. In the present disclosure, the term “integrally formed” refers to being formed as a single piece, and does not refer to a structural integration of separate components. As a result, material of the stud 202 is the same as material of the landing pad 204.

In some embodiments, one-third of the portion 202 of the conductive layer 108 is exposed by the landing pad 204. As a result, a contact area between the landing pad 204 and the stud 202 is relatively high, and therefore a structure formed by the landing pad 204 and the stud 202 is relatively robust.

In some embodiments, one-half of the portion 202 of the conductive layer 108 is exposed. As a result, a contact area between the landing pad 204 and the stud 202 is relatively high, and therefore a structure formed by the landing pad 204 and the stud 202 is relatively robust.

In the present disclosure, because a process of forming the landing pad 204 does not undergo the CMP process and the PVD process following the CMP process, the method of manufacturing the semiconductor device 13 is relatively simple, i.e., one-step process. In addition, since the landing pad 204 and the stud 202 are integrally formed and therefore have the same material, there is no need to provide an adhesive layer therebetween. Also, there is no need for concern whether an adhesion between the landing pad 204 and the stud 202 is sufficient. Moreover, since no CMP process is performed, there is no need for concern whether a mark for alignment in the subsequent photolithography process is damaged.

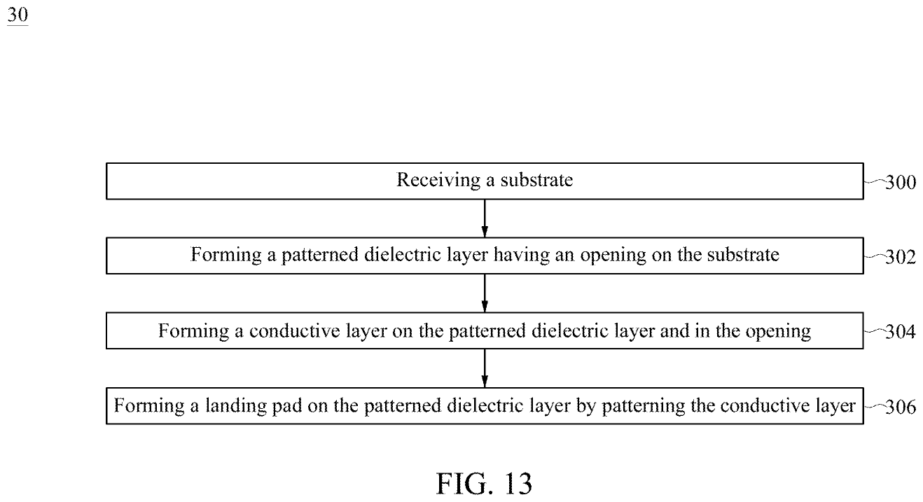

FIG. 13 is a flowchart of a method 30 of manufacturing a semiconductor device, in accordance with some embodiments of the present disclosure. Referring to FIG. 13, the method 30 includes operations 300, 302, 304 and 306.

The method 30 begins with operation 300, in which a substrate is received.

The method 30 proceeds to operation 302, in which a patterned dielectric layer having an opening is formed on the substrate.

The method 30 continues with operation 304, in which a conductive layer is formed on the patterned dielectric layer and in the opening.

The method 30 proceeds to operation 306, in which a landing pad is formed on the patterned dielectric layer by patterning the conductive layer.

The method 30 is merely an example, and is not intended to limit the present disclosure beyond what is explicitly recited in the claims. Additional operations can be provided before, during, and after the method 30, and some operations described can be replaced, eliminated, or moved around for additional embodiments of the method.

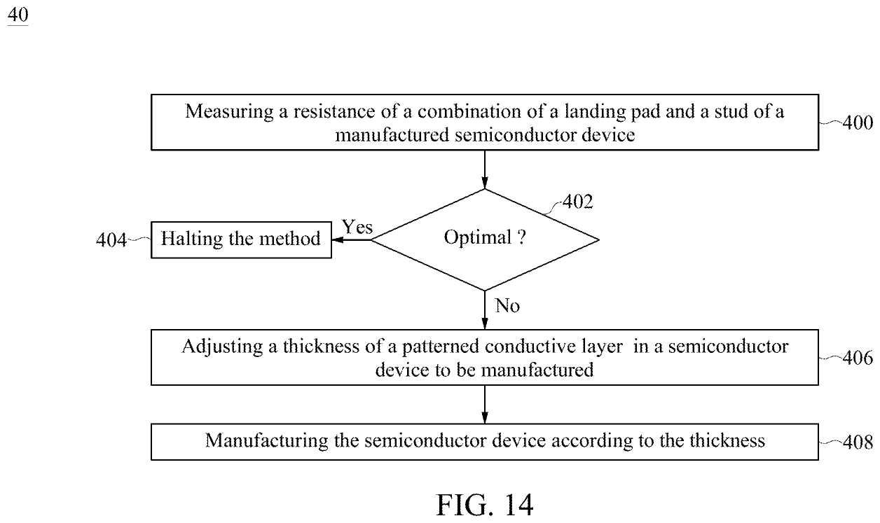

FIG. 14 is a flowchart of a method 40 of designing and manufacturing a device, in accordance with some embodiments of the present disclosure. Referring to FIG. 14, the method 40 includes operations 400, 402, 404, 406 and 408.

The method 40 begins with operation 400, in which a resistance of a combination of a landing pad and a stud of a manufactured semiconductor device is measured, wherein the landing pad and the stud are in a patterned conductive layer of the manufactured semiconductor device. The landing pad and the stud have the same material.

The method 40 proceeds to operation 402, in which it is determined whether the resistance is optimal. If affirmative, the method 40 proceeds to operation 404, in which the method 40 is halted. If negative, the method 40 continues with operation 406, in which a thickness of a patterned conductive layer in a semiconductor device to be manufactured is adjusted. In some embodiments, a thickness of a portion of the patterned conductive layer is adjusted, wherein the portion of the patterned conductive layer is disposed on a patterned dielectric layer of the semiconductor device to be manufactured.

The method 40 proceeds to operation 408, in which the semiconductor device is manufactured according to the thickness.

The method 40 is merely an example, and is not intended to limit the present disclosure beyond what is explicitly recited in the claims. Additional operations can be provided before, during, and after the method 40, and some operations described can be replaced, eliminated, or moved around for additional embodiments of the method.

In the present disclosure, the landing pad and the stud are integrally formed and therefore have the same material. Accordingly, there is a reduction in the complexity of the factors that determine electrical characteristics, such as resistance. The resistance can be adjusted simply by adjusting the thickness of a layer to form the land pad and the stud.

In contrast, referring back to FIG. 6, the landing pad 114 and the stud 110 are in two different conductive layers. Material of the landing pad 114 is different from material of the stud 110. Accordingly, many interrelated factors combine to determine electrical characteristics, such as resistance. It is relatively difficult to adjust the resistance. In addition, there is a need to consider adhesion between the landing pad 114 and the stud 110. For example, if the landing pad 114 is too thick in response to the adjustment of the resistance and the adhesion is not sufficient, the landing pad 114 will collapse.

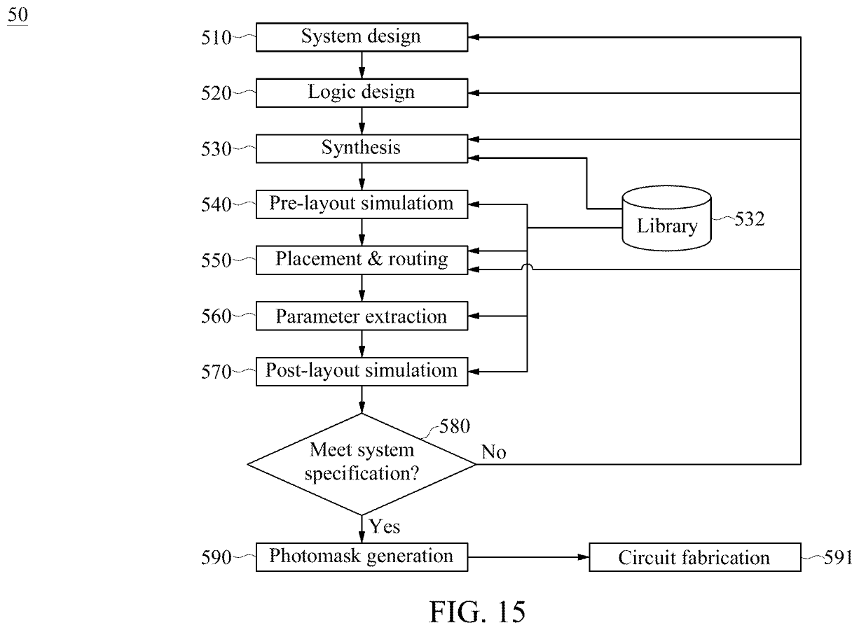

FIG. 15 is a schematic diagram illustrating a design flow 50 of an integrated circuit (IC), in accordance with some embodiments. The design flow 50, employed for designing semiconductor ICs or chips, utilizes one or more electronic design automation (EDA) tools to perform operations therein. A workstation or personal computer is typically used in executing the steps to accomplish the design flow 50. The design flow 50 includes a system design stage 510, a logic design stage 520, a synthesis stage 530, a pre-layout simulation stage 540, a placement and routing development stage 550, a parameter extraction stage 560, a post-layout simulation stage 570, a photomask generation stage 590 and a circuit fabrication stage 591.

Initially, during the system design stage 510, a systematic architecture for the chip of interest is provided with a high-level description. During the system design stage 510, the chip functions along with performance requirements are determined according to a design specification. The chip functions are usually represented by respective schematic functional modules or blocks. In addition, an optimization or performance trade-off may be sought to achieve the design specification at acceptable levels of cost and power.

During the logic design stage 520, the functional modules or blocks are described in a register transfer level (RTL) using a hardware description language. Commercially available language tools are generally used, such as Verilog or VHDL. In an embodiment, a preliminary functionality check is performed during the logic design stage 520 to verify whether the implemented functions conform to the specification set forth in the system design stage 510.

Subsequently, during the synthesis stage 530, the modules in the RTL descriptions are converted into an instance of design data, e.g., netlist data, where the circuit structure, e.g., logic gates and registers, of each function module are established. In an embodiment, a standard cell library 532 is provided to supply different classes of low-level circuits, i.e., standard cells, serving specific Boolean logic or sequential logic functions. In some embodiments, technology mapping of logic gates and registers to available cells in the standard cell libraries are conducted. Further, the design data or netlist data is provided to describe the functional relationship of the chip at a gate level. The standard cell library 532 may be provided by an IC designer, an IC manufacturing company, a computer-aided design (CAD) tool provider or any relevant third party. The standard cell library 532 also provides the parameters associated with each cell, such as the timing, power, voltage, and the like. In an embodiment, the netlist data is transformed from the gate-level view to a transistor-level view. In an embodiment, when the library is provided or updated (as will be described in subsequent paragraphs herein) and incorporated into the CAD tool, the IC designer can improve the updated library by identifying violations of the design rule (e.g., timing violations) and revise the original netlist data in response to the identified violations. In some embodiments, operation 406 is performed during the synthesis stage 530.

Subsequently, the gate-level netlist data is verified during the pre-layout simulation stage 540. During the verification process of the pre-layout simulation stage 540, if some functions fail the verification in the simulation, the design flow 50 may be paused temporarily or may go back to the system design stage 510 or the logic design stage 520 for further modification. After the pre-layout simulation stage 540, the chip design has passed a preliminary verification and the front-end design process is completed. Next, a back-end physical design process is conducted.

During the placement and routing stage 550, a physical architecture representing the chip, determined during the front-end process, is implemented. The layout development involves a placement operation and a routing operation in sequence. Detailed structures and associated geometries for the components of the chip are determined in the placement operation. Interconnects among different components are routed subsequent to the placement operation. Both placement and routing operations are performed to meet the requirements of a design rule check (DRC) deck so that the manufacturing constraints of the chip are fulfilled. In an embodiment, a clock tree synthesis operation is performed during the placement and routing stage for a digital circuit in which clock generators and circuits are incorporated into the design. In an embodiment, a post-routing operation is performed subsequent to the preliminary routing operation in order to resolve timing issues discovered during the preliminary routing operation. Once the placement and routing stage 550 is completed, a placed-and-routed layout is created and a netlist along with data on placement and routing is generated accordingly.

During the parameter extraction stage 560, a layout parameter extraction (LPE) operation is conducted to derive layout-dependent parameters, such as parasitic resistance and capacitance, based on the layout developed during the placement and routing stage 550. Subsequently, a post-layout netlist data, which includes the layout-dependent parameters, is generated.

During the post-layout simulation stage 570, a physical verification is performed, taking into consideration the parameters acquired during previous stages. A simulation of transistor-level behavior is conducted to examine whether the chip performance derived by the post-layout netlist meets the required system specifications. In some embodiments, the post-layout simulation is performed to minimize probability of electrical issues or layout difficulties during the chip manufacturing process. In an embodiment, the standard cell library 532 is provided not only to the operations in stage 530, but also to the operations in stages 540, 550, 560 and 570 so that the electrical or geometric parameters of cells and other features listed in the standard cell library 532 can be leveraged to emulate the real-world performance of the circuits throughout the design phase.

Next, during stage 580, it is determined whether the post-layout netlist meets the design specifications. If the result of the post-layout simulation is unfavorable, the design flow 50 loops back to previous stages for tuning functionalities or structures. For example, the design flow 50 may loop back to stage 550 where the layout is re-developed to resolve issues from a physical perspective. Alternatively, the design flow 50 may retreat to an earlier stage 510 or 520 to recast the chip design from a functional level in case the problems cannot be resolved within the back-end process.

If the post-layout netlist passes the verification, the circuit design is accepted and then signed off accordingly. The chip is manufactured according to the accepted post-layout netlist. In an embodiment, during stage 590, at least one photomask is generated based on the verified post-layout netlist in stage 570. A photomask is a patterned mask used to allow a portion of light to pass through while blocking other portions of the light in order to form a pattern of features on a light-sensitive layer, e.g., a photoresist layer, on a wafer. The photomask is used to transfer the patterns of the verified post-layout netlist onto wafers. In some embodiments, a multi-layer layout netlist may require a set of photomasks in which the feature pattern in each layer is established in the corresponding photomask. As a result, the patterns of the layout netlist formed on the photomasks are transferred to the light-sensitive layer through an exposure operation.

During stage 591, the circuit is fabricated on the wafer using the photomasks generated in stage 590. Operation 408 is performed during the placement and routing stage 591. The fabrication may involve known semiconductor manufacturing operations, such as lithography, etching, deposition, and thermal operations. In some embodiments, a testing operation may be utilized during an intermediate or final phase of stage 591 to ensure physical and functional integrity of the fabricated circuit. In some embodiments, a singulation operation may be used to separate the circuit wafer into individual circuit dies. The fabrication of the circuit is thus completed.

The design flow 50 illustrated in FIG. 15 is exemplary. Modifications to the above-mentioned stages, such as change of order of the stages, partition of the stages, and deletion or addition of stages, are within the contemplated scope of the present disclosure.

In the present disclosure, since a process of forming the landing pad does not undergo the CMP process and the PVD process following the CMP process, the method of manufacturing the semiconductor device is relatively simple. In addition, since the landing pad and the stud are integrally formed and have the same material, there is no need to provide an adhesive layer therebetween. Also, there is no need for concern whether an adhesion between the landing pad and the stud is sufficient. Moreover, since no CMP process is performed, there is no need for concern whether a mark for alignment in the subsequent photolithography process is damaged.

One embodiment of the present disclosure provides a semiconductor device. The semiconductor device includes a patterned insulation layer, a stud and a landing pad. The patterned insulation layer has an opening. The stud is disposed in the opening. The landing pad is disposed on the patterned insulation layer. The stud and the landing pad are integrally formed.

Another aspect of the present disclosure provides a method of manufacturing a semiconductor device. The method includes receiving a substrate. The method further includes forming a patterned dielectric layer having an opening on the substrate. The method further includes forming a conductive layer on the patterned dielectric layer and in the opening. The method further includes forming a landing pad on the patterned dielectric layer by patterning the conductive layer.

Another aspect of the present disclosure provides a method of designing and manufacturing a device. The method includes measuring a resistance of a combination of a landing pad and a stud of a manufactured semiconductor device, wherein the landing pad and the stud are in a patterned conductive layer of the manufactured semiconductor device. The method further includes adjusting a thickness of a patterned conductive layer in a semiconductor device to be formed, wherein the adjusting is performed when the resistance is not optimal. The method further includes manufacturing the semiconductor device according to the thickness.

The scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a patterned insulation layer having an opening;
a stud disposed in the opening; and
a landing pad disposed on the patterned insulation layer,
wherein the stud and the landing pad are integrally formed.

2. The semiconductor device of claim 1, wherein the landing pad exposes one-half of the stud.

3. The semiconductor device of claim 1, wherein the landing pad exposes one-third of the stud.

4. The semiconductor device of claim 1, wherein the landing pad is disposed on the stud.

5. The semiconductor device of claim 4, wherein the landing pad is disposed on one-half of the stud.

6. The semiconductor device of claim 4, wherein the landing pad is disposed on two-thirds of the stud.

7. A method of manufacturing a semiconductor device, comprising:
receiving a substrate;
forming a patterned dielectric layer having an opening on the substrate;
forming a conductive layer on the patterned dielectric layer and in the opening; and
forming a landing pad on the patterned dielectric layer by patterning the conductive layer.

8. The method of claim 7, wherein the formation of the conductive layer on the patterned dielectric layer and in the opening includes:
forming the conductive layer on the patterned dielectric layer and in the opening by a chemical vapor deposition (CVD).

9. The method of claim 7, wherein the formation of the conductive layer on the patterned dielectric layer and in the opening includes:
forming the conductive layer on the patterned dielectric layer and in the opening by plasma-enhanced CVD (PECVD).

10. The method of claim 7, wherein the formation of the landing pad on the patterned dielectric layer by patterning the conductive layer includes:
exposing a portion of a portion of the conductive layer, wherein the portion of the conductive layer is formed in the opening.

11. The method of claim 10, wherein the formation of the landing pad on the patterned dielectric layer by patterning the conductive layer further includes:
exposing the entire patterned dielectric layer except for a portion of the patterned dielectric layer under the landing pad.

12. The method of claim 10, wherein the exposure of the portion of the portion of the conductive layer includes:
exposing one-third of the portion of the conductive layer.

13. The method of claim 10, wherein the exposure of the portion of the portion of the conductive layer includes:
exposing one-half of the portion of the conductive layer.

14. A method of designing and manufacturing a device, the method comprising:
measuring a resistance of a combination of a landing pad and a stud of a manufactured semiconductor device, wherein the landing pad and the stud are in patterned conductive layers of the manufactured semiconductor device;
adjusting a thickness of a patterned conductive layer in a semiconductor device to be manufactured, wherein the adjusting is performed when the resistance is not optimal; and
manufacturing the semiconductor device according to the thickness.

15. The method of claim 14, wherein the adjustment of the thickness of the patterned conductive layer in the semiconductor device to be manufactured includes:
adjusting a thickness of a portion of the patterned conductive layer, wherein the portion of the patterned conductive layer is disposed on a patterned dielectric layer of the semiconductor device to be manufactured.
